(19) United States
(12) Patent Application Publication
(10) Pub. No.: US 2005/0276017 A1
(43) Pub. Date: Dec. 15, 2005

(54) Common plenum and air intake airflow management for telecom equipment

(76) Inventors: Farid Aziz, Kanata (CA); Thomas Currie, Ottawa (CA); Marko Nicolici, Ottawa (CA)

Correspondence Address: STEUBING AND MCGUINESS & MANARAS LLP, 125 NAGOG PARK, ACTON, MA, 01720, US

(21) Appl. No.: 10/865,532

(22) Filed: Jun. 10, 2004

(51) Int. Cl. H05K 7/20

(52) U.S. Cl. 361/695

(57) ABSTRACT

An air flow distribution system for a telecommunication equipment assembly is disclosed. The telecommunications equipment assembly includes a chassis. The chassis is formed by wall panels and includes a first side, a second side, a bottom end section, a top end section, electronic apparatuses regions and a plenum region having plenum region boundaries. The telecommunication equipment assembly also includes a first side air input port and a second side air input port in the bottom end section of the chassis. The input ports permit cooling air to be drawn into the chassis. An output port is provided in the top end section of the chassis. A fan holder is located along one of the plenum region boundaries. The fan holder receives a fan to facilitate air movement in conjunction with the plenum region. The air movement includes movement along air flow paths through the electronic apparatuses regions. The electronic apparatuses and plenum regions are located above the input ports and below the output port. The electronic apparatuses regions border another of the plenum region boundaries.

### FIELD OF THE INVENTION

This invention relates to housings and air flow distribution systems for telecommunication equipment assemblies and, in particular, a housing and method in which a plenum region within the housing or chassis of a telecommunications equipment assembly is employed in an air flow distribution system.

### BACKGROUND OF THE INVENTION

Most modern telecommunications equipment contain electronic components, devices or equipment mounted in a housing or chassis. The chassis is generally enclosed, with an access door, side walls, and a backplane. The chassis is enclosed to prevent stray material from entering the casing and damaging the electronic apparatus, and to prevent stray emission of electromagnetic energy. There can also be a midplane in the chassis. Although the term midplane suggests a location halfway between the backplane and the front of the chassis, this is not necessarily so.

In recent years, there has been a dramatic increase in functional density of telecommunications modules in regards to the reduction in space required for an amount of data process capability. At the same time, the power required to operate each module and the consequent heat generated has correspondingly increased in nearly as dramatic a fashion to the point where traditional vertically oriented or end-on-end oriented electronics modules within telecommunications systems have been or will soon be unable to realize the advantages of the functional densities now achievable as a result of heat limits.

There are a number of factors related to the ability to cool heated components in a chassis. One criterion for the rate of heat removal is the velocity of cooling air through air flow passages in the chassis. High velocity air is not enough though. A heat removal system will be ineffective if cooling air does not reach a substantial portion of heated components in the chassis.

U.S. Pat. No. 4,860,163 teaches a device for improving air flow over circuit modules. The patent describes a cabinet for holding circuit modules, with a fan, centrally located, drawing air from one end of the cabinet. There is a wall at one end of the modules closest to the fan preventing air from flowing directly from the modules to the fan. Instead, air must flow around the wall to reach the fan. To further improve air flow distribution, baffles are placed along a portion of the sides of the cabinet to force air to flow over at least a portion of the modules. For this device to help improve the evenness of air flow, it appears necessary that the fan be relatively centrally located. If, as in many electronics systems, the fan is not centrally located, air flow will not be significantly improved, if at all, in portions of the modules remote from the fan. It also appears that the device was not designed to be used in telecommunications devices having midplanes.

More recent U.S. Pat. No. 6,104,003 issued Aug. 15, 2000 describes a cabinet for housing telecommunications equipment that includes an enclosure with a subrack mounted therein. A duct delivers ambient air from outside through the bottom of the cabinet to the subrack. A subrack exit plenum is disposed above the electronic subrack for exhausting air heated by the electronics equipment. Fans are mounted above this plenum for drawing ambient air up from the inlet, through the subrack region, and through the plenum. However, this cabinet also does not appear to have a midplane extending vertically in the cabinet and to have electronic apparatuses mounted on both sides of the midplane.

Another recent patent which teaches a cabinet for electronic equipment is U.S. Pat. No. 6,538,881 which issued Mar. 25, 2003. In this cabinet, cooling air enters the cabinet through an inlet near the top of one side and then flows down through a first region of the cabinet to two fans located in the bottom of the cabinet. A portion of the cooling air can then exit through an output port in the bottom of the cabinet while another portion of the air flows upwardly through a second region of the cabinet that is separated from the first region by a vertical plate or midplane. Because of the return of cooling air into the first region from the second region, there is an accumulation of incoming and returned air passed along the first region in the cabinet.

It is an object to the present invention to provide an improved housing assembly for electronics equipment that has provision for air flow distribution.

It is a further object or another aspect of the invention to provide an improved method for providing air flow through a telecommunications equipment assembly.

### SUMMARY OF THE INVENTION

According to one aspect of the invention, there is provided a housing assembly for electronics equipment comprising an external housing including a front, a back, a vertical first side panel, a vertical second side panel opposite the first side panel, a bottom end section, and a top end section. The housing also has at least one output port formed in the top end section and at least one inlet port formed in the bottom end section. There is also provided at least one fan holder for at least one air circulating fan in one of the top end section and the bottom end section. An interior vertical wall is mounted in the external housing and extends between the first side panel and the second side panel. This interior vertical wall is located between the front and back of the external housing and separates first and second regions of the housing assembly for receiving electronic apparatuses. A plenum region has a first plenum side located adjacent the at least one fan holder and an opposite second plenum side located adjacent both of the first and second regions. The plenum region extends horizontally across one edge of the interior vertical wall. During use of this housing assembly, the at least one fan is mounted in the at least one fan holder and operates to create an air pressure differential in the plenum region and this air pressure differential produces an upwards air flow through both the first and second regions of the housing assembly in order to cool the electronic apparatuses.

In one embodiment, there are two of the fan holders and these are within the top end section of the external housing with the plenum region being located below the two fan holders.

According to another aspect of the invention, a method provides air flow through a telecommunications equipment assembly which comprises a housing having exterior walls defining an internal cavity and a midplane dividing this internal cavity into a switch side and a port side. A plenum region is formed in the housing so as to extend across one edge of the midplane and along a side of the internal cavity on both the switch side and the port side. Both the switch side and the port side contain a plurality of electronic apparatuses which form a plurality of vertically extending switch side flow channels and a plurality of vertically extending port side flow channels extending to the plenum region. The assembly also includes a fan section containing one or more fans in flow communication with and adjacent to the plenum region. The method of the invention comprises creating an air pressure differential in the plenum region by operating the one or more fans and thereby producing the air flow through both the port side flow channels and the switch side flow channels, this air flow being substantially in one vertical direction. The air flow through the port side flow channels and the switch side flow channels acts to cool the electronic apparatuses during use of the telecommunications equipment assembly.

In one form of this method, the air flow through both the port side flow channels and the switch side flow channels is upwardly and the plenum region extends across a top edge of the midplane.

According to another aspect of the invention, a telecommunications equipment assembly comprises an external housing having a front end, a back end, a vertical first side panel, a vertical second side panel opposite the first side panel, a bottom end section and a top end section. At least one output port is formed in the top end section and two inlet ports are formed in the bottom section and located on opposite sides of the bottom section. A fan holding device is mounted in the top end section and two or more fans are mounted on this fan holding device. An interior vertical wall is mounted in the external housing so as to extend substantially perpendicular to the first and second side panels. This vertical wall is positioned between and is spaced from the front and the back of the housing and has a upward edge spaced below the fan holding device. This vertical wall divides the housing into front and back cavity regions. A first set of electronic apparatuses is mounted in the front cavity region and forms vertically extending first air flow passages between adjacent pairs of the electronic apparatuses. A second set of different electronic apparatuses is mounted in the second cavity region and forms second, vertically extending air flow passages. A plenum region is formed in the housing between the front and back cavity regions and the fan holding device. The plenum region extends horizontally across an upper edge of the interior vertical wall. During use of this assembly, the two or more fans operate to create a pressure differential in the plenum region that produces upwards air flow through both the first and second air flow passages and into the plenum region.

In one embodiment of this assembly, the fan holding device extends horizontally in a front to back direction relative to the housing.

The present invention will be further understood from the following detailed description with reference to the accompanying drawings.

### BRIEF DESCRIPTION OF THE DRAWINGS

FIG. 1 is a diagrammatic illustration in a vertical plane of a prior art fan cooling system in a telecommunications equipment assembly.

FIG. 2 is a perspective view of an embodiment of a housing or chassis for the telecommunications equipment assembly, this view being taken from above and from the front side, according to an embodiment of the invention.

FIG. 3 is an end view of an embodiment of the telecommunications equipment assembly according to an embodiment of the invention.

FIG. 4 is an opposite end view of the telecommunications equipment assembly of FIG. 3.

FIG. 5 is a perspective view of a fan unit used in conjunction with the telecommunications equipment assembly of FIGS. 3 and 4, this view being taken from above and showing two vertical sides.

FIG. 6 is a perspective view of the telecommunications equipment assembly of FIG. 3 attached to a frame.

FIG. 7A is a simplified cut away side view of an embodiment of the telecommunications equipment assembly illustrating first air flow paths.

FIG. 7B is another simplified cut away side view of the telecommunications equipment assembly of FIG. 7A illustrating second air flow paths.

FIG. 7C is yet another simplified cut away side view of the telecommunications equipment assembly of FIG. 7A illustrating third air flow paths.

FIG. 8 is a contour graph illustrating temperature inside an embodiment of the telecommunications equipment assembly.

### DETAILED DESCRIPTION

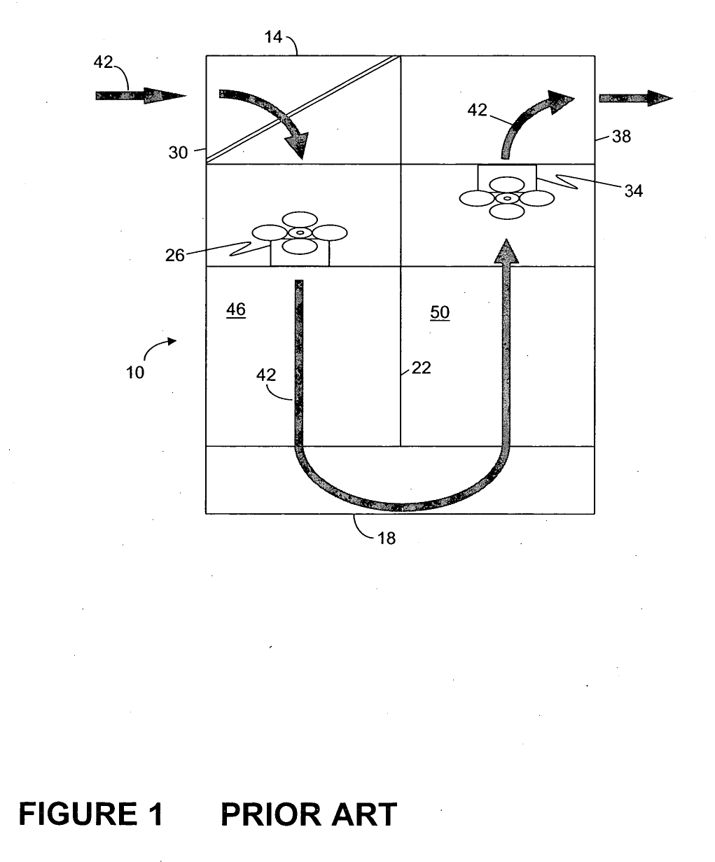

An example of a prior art fan cooling system is illustrated in FIG. 1. Housing or chassis 10 has a top wall 14 and a bottom wall 18. A divider mechanism 22 for the chassis 10 extends downwardly from the wall 14. In this prior art system, intake fan 26 draws in air from input port 30. On the opposite side of the divider mechanism 22 there is an exhaust fan 34 which exhausts air through output port 38. This configuration allows the fans 26 and 34 to move air through the chassis 10 in the direction indicated by arrows 42. As air flows through the chassis 10, electronic apparatuses located in regions of the chassis (e.g. regions 46 and 50) are cooled by the passing air.

While the above described fan cooling system may be satisfactory in uniformly cooling electronic apparatuses in the chassis 10 when the fans 26 and 34 are working properly, cooling will be non-uniform in the event of fan failure. For example, if the fan 26 fails, only the fan 34 will remain in operation. The average velocity of air flowing in the region to the left of the divider mechanism 22 will be less than the average velocity of air flowing in the region to the right of the divider mechanism 22. Consequently electronic apparatuses located in the region 46 may be inadequately cooled.

Another problem is the direction in which air moves. Air flowing in the region to the left of the divider mechanism 22 flows downwardly as opposed to upwardly. As electronic apparatuses in the chassis 10 begin to heat up there will be an upward air convection which will work against the downward flow.

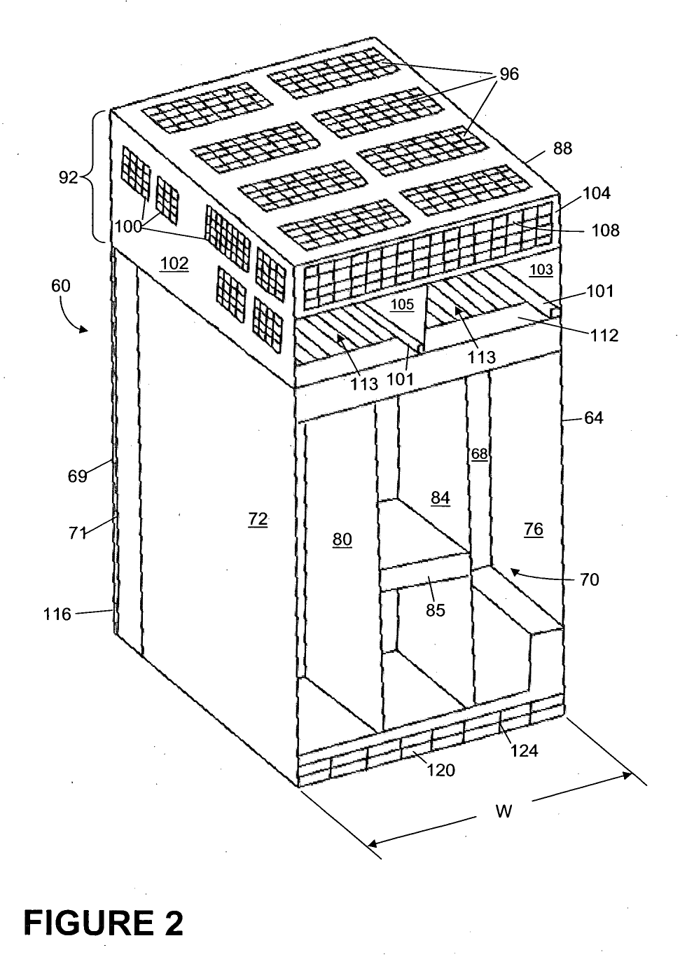

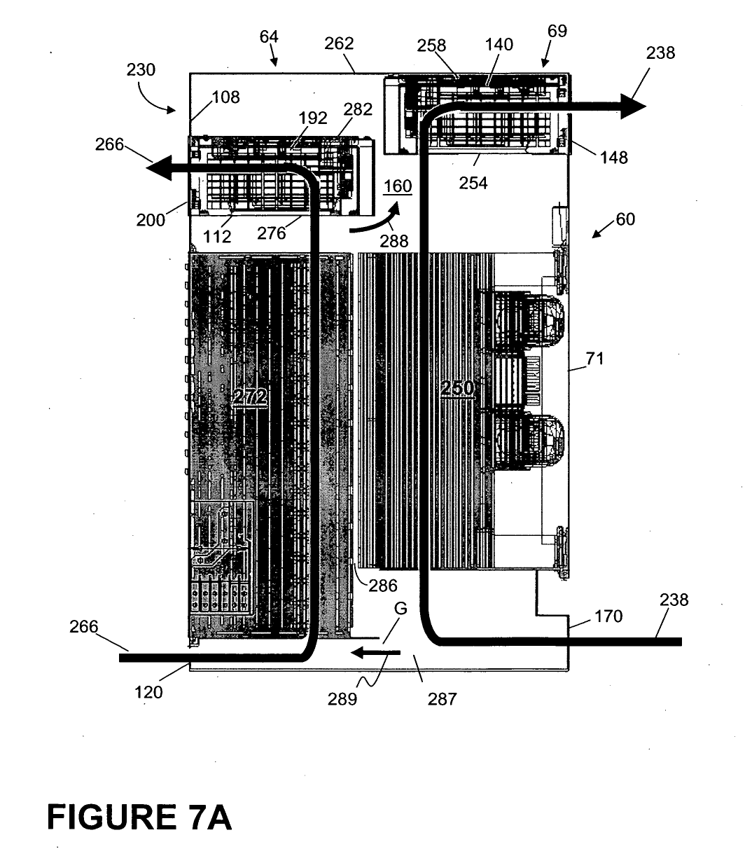

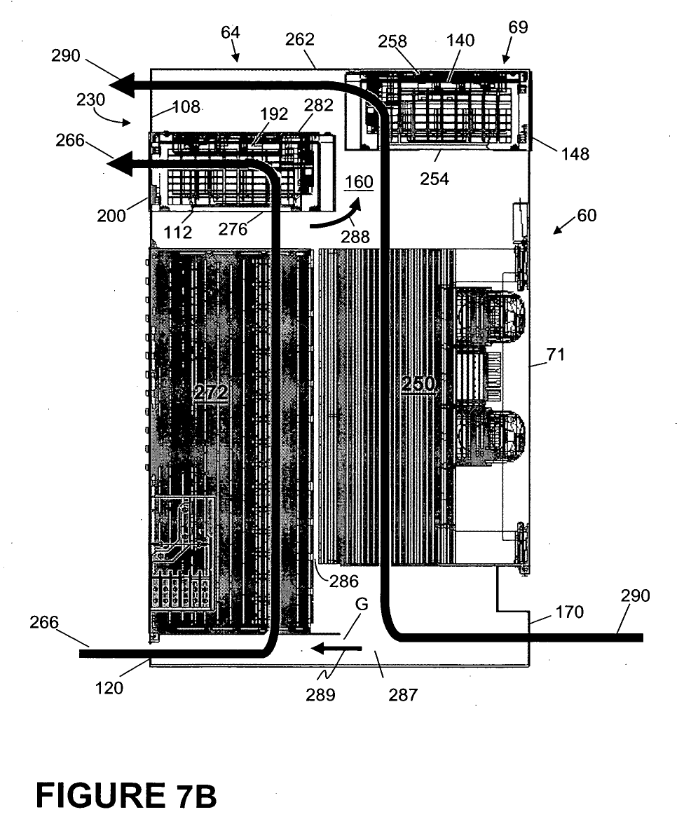

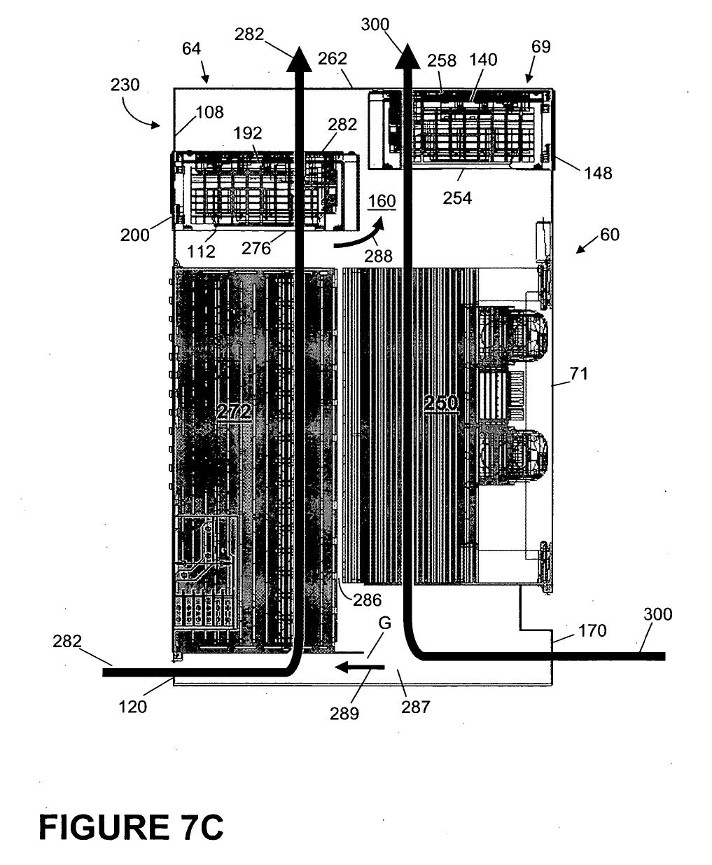

Referring to FIGS. 2 and 7A-7C, chassis or housing assembly 60 suitable for electronics equipment and, in particular, telecommunications equipment is constructed according to an embodiment of the present invention. In one embodiment the chassis 60 has a height of approximately 38.5 inches, and a width W of approximately 19.6 inches. The chassis 60 has a first side or switch side 64, a midplane 68 that extends vertically, a second side or port side 69, and backplane 71. The first side 64 is at the front of the housing while the second side is at the back.

The backplane 71 includes a printed circuit board that extends substantially the width W. The circuitry of the backplane 71 is well-known in the telecommunications industry. These details need not be appreciably discussed herein; however shielding is provided, as well as certain conductor path characteristics, including controlled impedance, current carrying capacity, paths for instrument busses, data busses, unit under test stimulus busses, and power busses.

The chassis 60 also defines a cavity 70, the cavity 70 being divided in two by the midplane 68. Thus the midplane 68 separates first and second regions of the housing assembly and thus it is a special form of interior vertical wall that extends between two exterior panels 72 and 76 of the housing. The circuitry of the midplane 68 is well-known in the telecommunications industry. The circuitry details are not appreciably discussed herein except as to assist in understanding the present invention. The switch side 64 is located on one side of the midplane 68, and the port side 69 is located on the other side of the midplane 68. Although the term midplane suggests a location half way between the backplane and the front of the chassis, this is not necessarily the case.

As indicated, the first and second side panels 72 and 76 form exterior walls of the chassis 60 and they extend vertically. The panels 72 and 76 are spaced apart and on opposite sides of the external housing. The switch side 64 is divided into compartments by vertical divider panels or walls 80 and 84 and, optionally, a horizontal divider panel 85 can extend between and connect the panels 80 and 84. The chassis 60 and the various panels can be made with sheet metal, injection molded plastic, or other similarly suited structural materials.

The chassis 60 preferably includes a fan cage 88 in top end section 92 of the housing. The top of the fan cage 88 has eight grill areas 96. The grill areas 96 are designed to permit air to pass in and out of the fan cage 88 while preventing large objects from falling into the fan cage 88. Sides of the fan cage 88 also have grill areas 100. Rails 101 for slidably receiving fan units extend along sides 102 and 103 of the fan cage 88, as well as along central divider 105.

A grill 104 covers and forms an output port 108 located in top end section 92. The dimensions of the output port 108 in one version of the assembly are approximately 4.0 inches by 19.6 inches. At the bottom of the fan cage 88 are fan holders or holding devices 112 for receiving fan units (not illustrated in FIG. 2). Also at the bottom of the fan cage 88 are backdraft louvers or dampers 113. The louvers 113 can close to prevent passage of air when the adjacent fan unit is off. This prevents recirculation of air through any fans that are not in use. The louvers 113 also prevent relatively large objects from being sucked into the fan cage and possibly damaging fan units located therein. Although two fan holders 112 are shown, it is also possible to construct the housing assembly of the invention with just a single fan holder or more than two fan holders. Each louver 113 extends horizontally in a front to back direction relative to the housing. The illustrated two fan holders extend from the first side panel 72 to the second side panel 76.

As an alternative to using the illustrated type of removable fan units, fixed fans (which are less easily removed) can be provided in the assembly. In this case, the fan holders or fan holding devices would be different than the fan holders 112. The fan holding devices or fan holders for this alternative embodiment could include screws and holes for the screws.

In bottom end section 116 of the chassis 60, there is a first side air input port or switch side air input port 120 and a second side air input port or port side air input port 170. The switch side air input port 120 in one embodiment has a height of approximately 1.5 inches. A grill 124 covers the switch side air input port 120. The grill 124 prevents relatively large sized objects from being sucked into the chassis 60. The air input port can extend across the front of the housing.

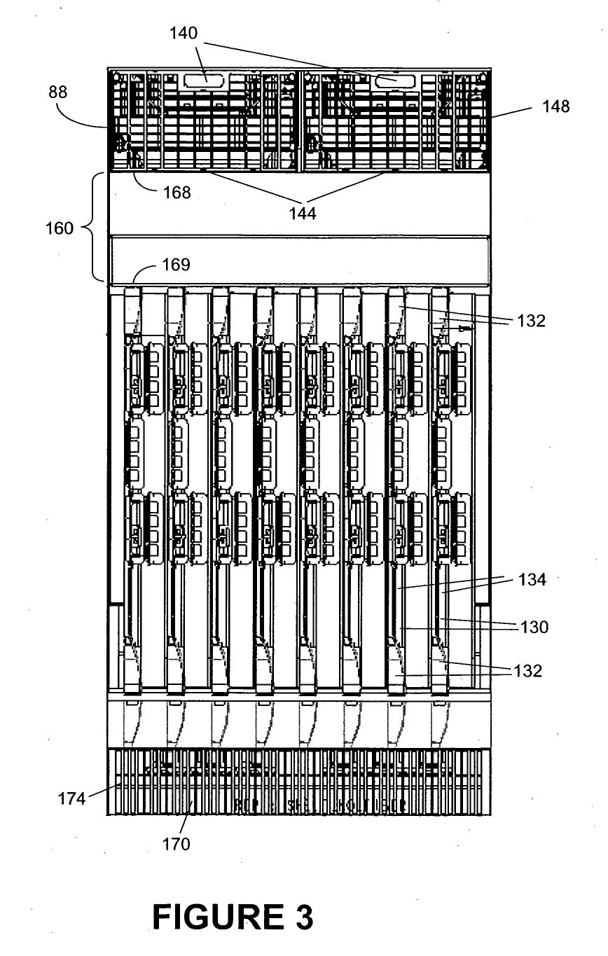

In FIG. 3, removable electronic apparatuses 130 have been inserted into an electronic apparatuses region of the chassis 60, and more specifically an electronic apparatuses region (also referred to herein as the second region) located in the port side 69 of the chassis 60. Latches 132 help to keep the electronic apparatuses 130 from becoming dislodged from their respective slots. The electronic apparatuses 130 of the port side 69 can have details of configuration and operation well known to those skilled in the art. These details are not appreciably discussed herein except as to assist in understanding the present invention.

The electronic apparatuses 130 include circuit boards which interconnect electronic components. The circuit boards for the electronic apparatuses 130 (not illustrated in FIG. 3) are behind each of vertically arranged face plates 134. The circuit boards are arranged vertically so as to create vertical air flow channels (also not illustrated in FIG. 3) between the circuit boards. This vertical arrangement is more streamlined than other arrangements and allows upward air flow through the second region from the aforementioned port side input port 170.

Two fan units 140 have been slidably mounted in fan holders or holding devices 144 in the fan cage 88. It will be appreciated that for certain embodiments less than two fans will be adequate; however for the illustrated embodiment a plurality of fans is preferred. For example, a second fan provides redundancy in case of fan failure. The two fan units can be mounted at different heights in the fan cage (as shown).

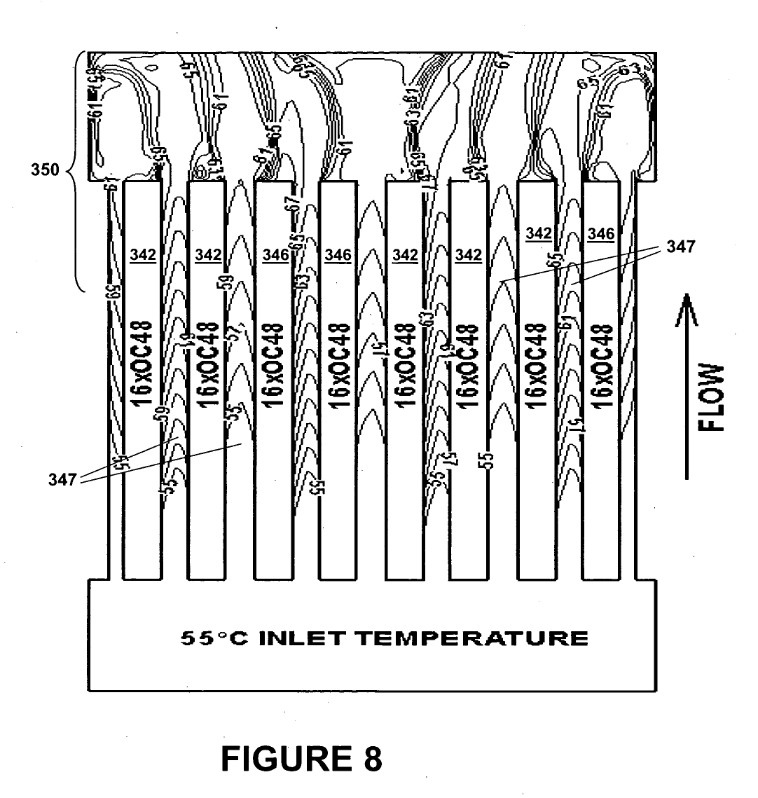

An output port 148 can span across the width and depth of the two fan units 140 as shown in FIG. 3. Plenum region 160, which in the illustrated embodiment will have an operating pressure less than ambient, is below the fan units 140 and above the electronic apparatuses 130. Creating an air pressure differential in the plenum region 160 facilitates the forcing or drawing of air through vertical air flow channels formed between the electronic apparatuses (such as the vertical air flow channels 347 shown in FIG. 8). The plenum region 160 has boundaries including upper boundary 168 and lower boundary 169. The fan holders 144 are located along the boundary 168. The electronic apparatuses 130 border the boundary 169.

The port side air input port 170 is located at the bottom of the chassis and is below electronic apparatuses 130. The port side air input port 170 has a height of approximately 3.4 inches in the illustrated embodiment. The port side air input port 170 is also covered by a grill 174. The grill 174 prevents relatively large sized objects from being sucked into the chassis 60. As shown, the port side input port 170 can extend across the back of the housing.

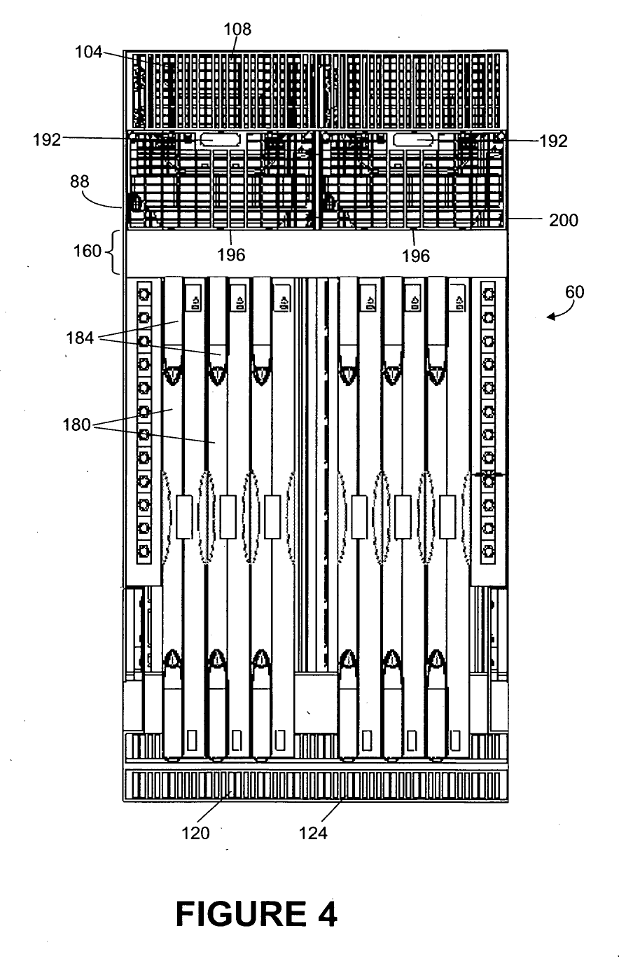

The switch side 64 is illustrated in FIG. 4. Removable electronic apparatuses 180 have been inserted into an electronic apparatuses region of the chassis 60, and more specifically a first region for electronic apparatuses located on the switch side 64 of the chassis 60. There are latches 184 to help keep the electronic apparatuses 180 from becoming dislodged from their respective slots. The electronic apparatuses 180 on the switch side 64 can have details of configuration and operation well known to those skilled in the art. These details are not appreciably discussed herein except as to assist in understanding the present invention.

Circuit boards for the electronic apparatuses 180 (not illustrated in FIG. 4) are behind each of vertically arranged face plates 188. The circuit boards are arranged vertically so as to create vertical air flow channels between the circuit boards. This vertical arrangement is more streamlined than other arrangements and allows upward air flow through the first region from the switch side input port 120.

Shown in FIG. 4 are two fan units 192 slidably mounted in fan holders 196 in the fan cage 88. It will be appreciated that for certain embodiments less than two fans will be adequate; however a plurality of fans is preferred. For example, a second fan provides redundancy in case of fan failure.

The fan unit 140 or 192 can be a fan of variable speed over a wide range of speeds. Optionally, fan speed sensors can be provided to detect fan failure or malfunctioning (e.g. detected speed is 75% or less than desired speed) of one of the fan units 140 or 192, in which case the speed of all of the remaining properly functioning fans can be increased. In other words, fan control means can be provided to selectively adjust the operational speed of the fan unit(s) that has not failed when the other fan has failed or is malfunctioning according to the sensor.

In one embodiment a control module is provided. This control module can control the speed of the fan units 140 and 192. Fan control modules of this type are known to those skilled in the art. U.S. Pat. No. 5,999,403 discloses a control module for varying the speed of a similar type of fan unit.

An output port 200 spans across the width and height of the fan units 192. The output port 200 is adjacent and below the output port 108. The output ports 108 and 200 are equally wide; however the output port 200 has a greater height in the embodiment of FIG. 4. The plenum region 160 is below the fan units 192 and above the electronic apparatuses 180.

In the embodiment of the equipment assembly illustrated in FIGS. 3 and 4, the height of the plenum region in the port side is approximately 6 inches, and the height of the plenum region in the switch side is approximately 2.4 inches. The required height of the plenum region in either the port side or the switch side is related to how densely the electronic apparatuses 130 or 180 are packed beside each other. The higher the density, the greater the required height. A greater height permits better dispersion of intense heat columns.

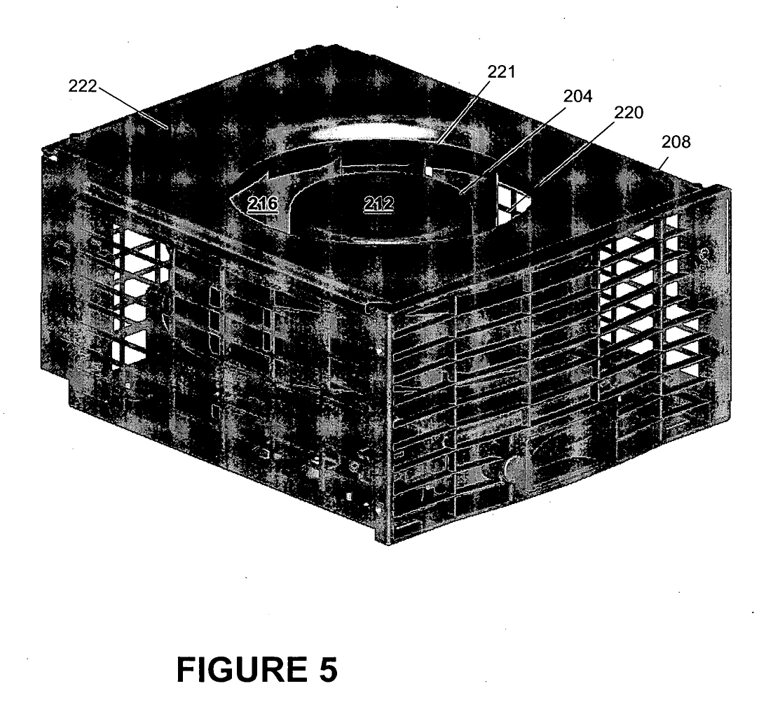

FIG. 5 illustrates a fan unit (i.e. the fan unit 192 of FIG.4 or the fan unit 140 of FIG. 3) used in conjunction with an embodiment of the invention. The illustrated fan unit is a motorized impeller type fan and includes an impeller 204 and a grille housing 208. The impeller 204 has a central cylindrical hub 212 and a plurality of blades 216 mounted on the hub 212. The impeller 204 is driven by a motor (not illustrated). As the impeller 204 is rotated, air is initially drawn through passageway 220, in an axial direction. Air is subsequently expelled through the vertical sides of the housing 108. The vertical sides of the housing 208 are each selectively closeable, and which sides are closed depends on the desired direction of air flow from the fan unit. Blocking air passage through one of the vertical sides of the housing 208 can be done through the use of baffles which are insertable at any one of the open vertical sides.

If desired, air flow can be directed through an annular fan outlet 221 formed in topside covering 222 of the fan unit instead of through one or more of the vertical sides of the housing 208. This is achieved by covering all of the open vertical sides with baffles. Alternatively, the same effect can be achieved by using an axial type fan instead of a motorized impeller type fan.

In the embodiment illustrated in FIGS. 3, 4 and 6, telecommunications equipment assembly 230 is a core node suitable for interfacing with a bi-directional line switched ring and/or routers. Interconnected core nodes can be found in a core network. Core networks are typically a combination of switching offices and a transmission plant connecting switching offices together.

It will appreciated that the air flow distribution apparatus of the present invention can be employed in telecommunications equipment assemblies besides core nodes suitable for interfacing with a bi-directional line switched ring and/or routers. The air flow distribution apparatus of the present invention is particularly effective in telecommunications equipment assemblies having dimensions similar to the illustrated embodiment and having power consumption in the range of 4 kW to 4.5 kW.

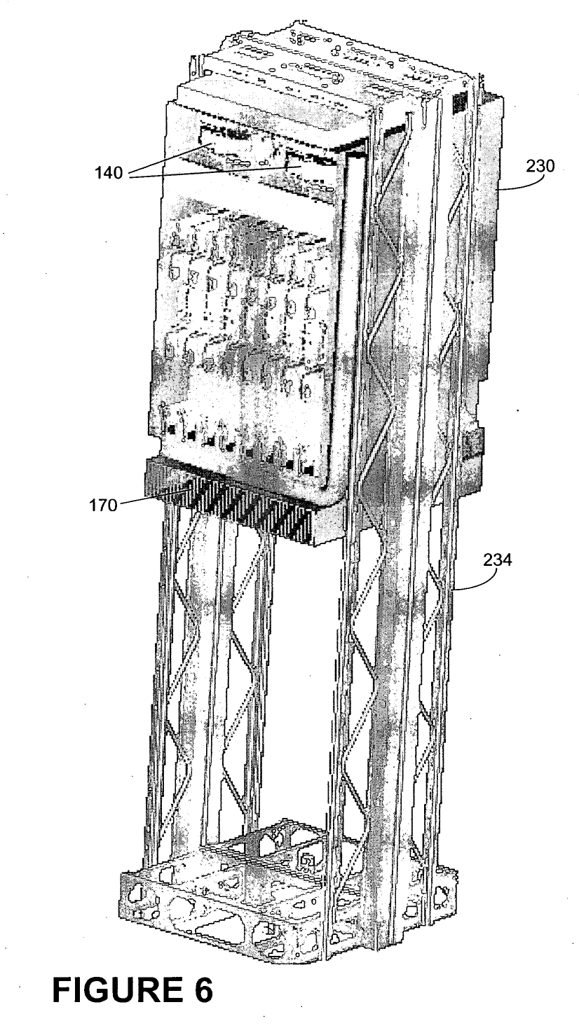

The telecommunications equipment assembly 230 is attached to a support frame 234 in FIG. 6. For some applications the frame 234 should be capable of meeting Seismic Zone 4 requirements. One possible frame which can be used is the PTE 2000 EA 600×600 mm sold by CMP Advanced Mechanical Solutions. A suitable height for the frame 234 is 2.125 m.

There is a space below the equipment assembly 230 suitable for accommodating the attachment of additional equipment to the frame 234. For instance an OM 3500™ sold by Nortel Networks could be attached. Alternatively, another equipment assembly substantially identical to the equipment assembly 230 could be attached. In this last case, the total load weight (not including the frame weight) could be well over 1200 lbs. One skilled in the art will appreciate however that there would rarely be a need to have two core nodes of the type illustrated on the frame 234. The illustrated equipment assembly 230 is currently designed to accommodate traffic for a city having a million people.

A first possible set of air flow paths for the telecommunications equipment assembly 230 is illustrated in FIG. 7A. Air flow arrow 238 illustrates air flow through the port side 69 of the equipment assembly 230. More specifically, air is first sucked in through the port side air input port 170. Air then travels upwardly through the vertical air flow channels between circuit boards 250. Air enters the fan unit 140 through inlet 254 and exits through the output port 148. Top fan outlet 258 of the fan unit 140 can be prevented from exhausting air through ceiling 262 of the telecommunications equipment assembly 230 if necessary by suitable closure means known to those skilled in the art. Closure means may not be necessary if the fan unit 140 is a motorized impeller type fan. When the fan unit is the one illustrated in FIG. 5, no baffles need to be inserted into the fan unit to achieve the FIG. 7A configuration. The operation particulars of the fan unit 140 will in part dictate the speed at which air flows along the illustrated course.

Air flow arrow 266 illustrates air flow through the switch side 64 of the equipment assembly 230. More specifically, air is first sucked in through the switch side air input port 120. This air flow in switch side portion of the bottom plenum region 287 is complemented by air drawn in through the port side inlet 170 and flowing underneath the divider mechanism through the gap G. Air then travels upwardly through the vertical air flow channels between circuit boards 272. Air enters the fan unit 192 through inlet 276 and exits through the output port 200. Top fan outlet 282 of the fan unit 192 can be prevented from exhausting air through the ceiling 262 by suitable closure means known to those skilled in the art. Alternatively, closure means can be provided immediately above the outlet 282. Closure means may not be necessary if the fan unit 192 is a motorized impeller type fan. When the fan unit is the one illustrated in FIG. 5, no baffles need to be inserted into the fan unit to achieve the FIG. 7A configuration. The operation particulars of the fan unit 192 will in part dictate the speed at which air flows along the illustrated course.

FIGS. 7A to 7C show an apparent space 286 extending between the circuit boards 250 and 272. However, it will be understood that in one embodiment of the invention, the space 286 is filled with a divider mechanism such as a midplane. One effect of a midplane is to separate air flow in the switch side 64 from air flow in the port side 69. In one embodiment, the divider mechanism extends vertically from the bottom of the fan unit 192 to the switch side top of bottom plenum region 287. In this version of the equipment assembly, there is a gap G beneath the divider mechanism.

The portion of the plenum 287 in the switch side 64 is interconnected with the portion of the plenum 287 in the port side 69 because of the gap G. Therefore there is air flow between these portions, such as is indicated by air flow directional arrow 289. The gap G (previously discussed) permits more unequal inlet areas on the port and switch sides than would otherwise be possible. With reference to FIG. 3 and FIG. 4, the switch side air input port 120 is substantially smaller than the port side air input port 170.

Likewise the portion of the plenum 160 in the switch side 64 is interconnected with the portion of the plenum 160 in the port side 69. Therefore there is small air flow between these portions, such as is indicated by air flow directional arrow 288. Air flow between the two plenum portions significantly reduces the impact of a fan fail. In the absence of the plenum region 160 characterized by the interconnected plenum portions, fan failure in the port side 69 would result in non-uniform cooling. In particular, the circuit boards 250 would be less adequately cooled as compared to the circuit boards 272. Likewise fan failure in the switch side 64 would result in the converse non-uniform cooling situation occurring.

The plenum region 160 reduces non-uniform cooling in the event of fan failure in either the switch side 64 or the port side 69. For example, there could be a port side fan failure in which the fan unit 140 would cease to operate. In this case, air flow into the plenum region 160 from the port side 69 which would normally be drawn into the fan unit 140 would instead be drawn into the fan unit 192. Thus the fan unit 192 is able to accommodate cooling of both the switch side 64 and the port side 69.

It will be appreciated that the air flow distribution apparatus of the present invention can be employed to improve air flow distribution regardless of whether the particular telecommunications equipment assembly includes or does not include a midplane. The midplane is simply one preferred way to divide the air flow between the two sides of the telecommunications equipment assembly but other forms of vertical dividers or walls are possible. Furthermore reference in this application to first and second sides in a telecommunications equipment assembly does not imply that telecommunications equipment assembly has both a port and switch side.

In one particular embodiment of the invention, fan failure detection means known to those skilled in the art is provided. Once a fan failure is detected, various responses can occur. First, an indicator light on the exterior of the equipment assembly 230 can be provided to indicate the fan failure. Second, the speed of the fan(s) which have not failed can be increased (assuming that they are not already at their maximum speed). Third, output port(s) of the failed fan can be closed. One skilled in the art will appreciate that doing this prevents unwanted air flow through the output port(s) of the failed fan. Alternatively, louvers can be used over an outlet to prevent inward air flow through the outlet.

A second possible set of air flow paths for the telecommunications equipment assembly 230 is illustrated in FIG. 7B. Air flow arrow 290 illustrates air flow originating from the port side 69 of the equipment assembly 230. Like in FIG. 7A, air is first sucked in through the port side air input port 170. Air again travels upwardly through the vertical air flow channels between the circuit boards 250. Air enters the fan unit 140 through the inlet 254; however instead of the air exiting through the output port 148, that port is closed and the fan unit 140 exhausts air through the output port 108 instead. With respect to the switch side 64, air flow is substantially the same as in FIG. 7A and is illustrated by the air flow arrow 266.

Thus when the telecommunications equipment assembly output ports are configured as illustrated in FIG. 7B, no air is exhausted through the port side 69. Thus the output port configuration of FIG. 7B is desirable where the equipment assembly 230 is kept in facilities that require air be exhausted through one side only. The configuration of FIG. 7B is used in North America.

A third possible set of air flow paths for the telecommunications equipment assembly 230 is illustrated in FIG. 7C. Air flow arrow 300 illustrates air flow through the port side 69 of the equipment assembly 230. Like in FIG. 7A, air is first sucked in through the port side air input port 170. Air again travels upwardly through the vertical air flow channels between the circuit boards 250. Air enters the fan unit 140 through the inlet 254; however instead of the air exiting through the output port 148, that port is closed and an output port is provided in the ceiling 262 instead so that the fan unit 140 (which is baffle configured as previous described to exhaust air in a vertical direction) exhausts air through the top fan outlet 258.

With respect to the switch side 64 of the equipment assembly 230, air flow arrow 306 illustrates air flow through that side. Like in FIG. 7A, air is first sucked in through the switch side air input port 120. This air flow in the switch side portion of the bottom plenum region 287 is complemented by air drawn in through the port side inlet 170 and flowing underneath the divider mechanism through the gap G. Air again travels upwardly through the vertical air flow channels between the circuit boards 272. Air enters the fan unit 192 through the inlet 276; however instead of the air exiting through the side output port 200, that port is closed, an output port is provided in the top or ceiling 262, and the fan unit 192 (which is baffle configured as previous described to exhaust air in a vertical direction) exhausts air through the top fan outlet 282.

Thus when the telecommunications equipment assembly output ports are configured as illustrated in FIG. 7C, substantially no air is exhausted outwardly from the port side 69 or the switch side 64. The output port configuration of FIG. 7C is desirable where the equipment assembly 230 is being used in certain European countries.

Although FIGS. 7A-7C illustrate embodiments in which the fan units are above the plenum region 160, and the plenum region 160 is above the air flow channels between the circuit boards, one skilled in the art will appreciate that other arrangements are possible. For example, the fan units instead of being located adjacent the output ports 148 and 200 could instead be located proximate the switch side air input port 120 and the port side air input port 170. In this case there would be a plenum region directly above the fan units, and this plenum region would function in a manner similar to the plenum region 160. Also the plenum region 160 would have a pressure above instead of below ambient.

As can be best seen in FIGS. 7A-7C, the fan units 140 are mounted at a different height than the fan units 192. The fan holders in the port side 69 are located higher in equipment assembly than the fan holders 64 in the switch side. This design permits the air flow arrangement illustrated in FIG. 7B. In that arrangement the fan units 192 would interfere with air flow along the path 290 if the fan units 140 and the fan units 192 were not at different heights. Having the fan units at different heights may also prevent cable connectors for the fan units 140 from mechanically interfering with cable connectors for the fan units 192.

FIG. 8 graphically illustrates possible temperature measurements within an embodiment of the telecommunications equipment assembly. FIG.8 is a port side vertical cross-section of the cavity holding electronic apparatuses, and the cross-section is superimposed with temperature contour lines.

Vertically oriented electronic apparatuses 342 and 346 could be the following: 16xOC48s 342 and QUAD 10Gs 346. It will be appreciated by one skilled in the art that the port side electronic apparatuses 342 and 346 are usually covered by clamshells.

There are vertical air flow channels between the electronic apparatuses 342 and 346. Vertical air velocity is greatest in the port side flow channels 347 formed between adjacent pairs of the electronic apparatuses as compared to the other regions illustrated. For both the switch side and the port side, exhaust air velocities can exceed 10 m/s at certain locations in the housing assembly. If there is neighboring equipment, there are various ways of ensuring that the exhaust air does not directly feed this neighboring equipment.

The contour map of FIG. 8 illustrates that the temperature is generally greatest in upper region 350. Numbers shown on the contours indicate the temperature of the contours in degrees Celsius. These temperature values are associated with an inlet temperature of 55° C. It will be appreciated by one skilled in the art that electronic apparatuses such as those illustrated in FIG. 8 usually need to be kept at temperatures below 70° C.

Numerous modifications, variations and adaptations may be made to the particular embodiments of the invention described without departing from the scope of the invention, which is defined in the claims.

1. A housing assembly for electronic equipment comprising:
an external housing including a front, a back, a vertical first side panel, a vertical second side panel opposite said first side panel, a bottom end section, and a top end section, and having at least one output port formed in said top end section and at least one inlet port formed in the bottom end section;
at least one fan holder for at least one air circulating fan within one of said top end section and said bottom end section;
an interior vertical wall mounted in said external housing and extending between said first side panel and said second side panel, said interior vertical wall located between the front and back of the external housing and separating first and second regions of the housing assembly for receiving electronic apparatuses; and
a plenum region having a first plenum side located adjacent said at least one fan holder and an opposite second plenum side located adjacent both of said first and second regions, said plenum region extending horizontally across one edge of said interior vertical wall,
wherein, during use of said housing assembly, said at least one fan is mounted in said at least one fan holder and operates to create an air pressure differential in said plenum region and said air pressure differential produces an upwards air flow through both said first and second regions of the housing assembly in order to cool said electronic apparatuses.

2. A housing assembly according to claim 1 wherein there are two of said at least one fan holder, said two fan holders are within said top end section of the external housing, and said plenum region is below said two fan holders.

3. A housing assembly according to claim 1 wherein said interior vertical wall is a midplane provided with electronic circuitry and said plenum region extends across a top edge of the midplane.

4. A housing assembly according to claim 3 wherein said first region is on a switch side of the housing assembly and is adapted to receive a first set of said electronic apparatuses and said second region is on a port side of the housing assembly and is adapted to receive a second, different set of electronic apparatuses.

5. A housing assembly according to claim 2 wherein said two fan holders are located at substantially different vertical heights, and are located on different sides of the housing assembly.

6. A housing assembly according to claim 2 wherein there are at least two of said at least one output port formed in a horizontal top of said top end section and there is a fan unit mounted in each of said two holders, each fan unit having an open fan outlet in a top side of the fan unit arranged to direct air flow to a respective one of the output ports.

7. A housing assembly according to claim 6 including sensor means for detecting a failure of either fan unit and means for selectively adjusting the operational speed of one of the fan units that has not failed when the other fan unit has failed according to said sensor means.

8. A housing assembly according to claim 1 wherein said housing assembly is adapted to hold telecommunications equipment and has a switch side and a port side and a plurality of fans are mounted in said at least one fan holder.

9. A housing assembly according to claim 2 wherein said top end section of the external housing is a fan cage having a plurality of grill areas located in two or more sides of the fan cage.

10. A housing assembly according to claim 1 wherein there are two of said at least one output port formed in said top end section, there are two of said at least one inlet port formed in said bottom end section, and the two inlet ports are located at opposite ends of the bottom end section.

11. A method for providing air flow through a telecommunications equipment assembly, said assembly comprising a housing having exterior walls defining an internal cavity and a midplane dividing said internal cavity into a switch side and a port side, a plenum region being formed in said housing so as to extend across one edge of said midplane and along a side of said internal cavity on both said switch side and said port side, both said switch side and said port side containing a plurality of electronic apparatuses which form a plurality of vertically extending switch side flow channels and a plurality of vertically extending port side flow channels extending to said plenum region, said assembly also including a fan section containing one or more fans in flow communication with and adjacent to said plenum region, said method comprising:
creating an air pressure differential in said plenum region by operating said one or more fans; and thereby producing said air flow through both said port side flow channels and said switch side flow channels, said air flow being substantially in one vertical direction,
said air flow through said port side flow channels and said switch side flow channels acting to cool said electronic apparatuses during use of the telecommunication equipment assembly.

12. A method according to claim 11 wherein said air flow through both said port side flow channels and said switch side flow channels is upwardly and said plenum region extends across a top edge of said midplane.

13. A method according to claim 12 wherein there are two or more fans in said fan section which includes at least one fan holding device supporting said fans.

14. A method according to claim 13 wherein said midplane is a vertical wall extending between two side walls, that are part of said exterior walls, and having electronic circuitry and connectors mounted thereon.

15. A method according to claim 14 wherein said telephone equipment assembly is a core node having a power consumption of at least 4 kW.

16. A telecommunications equipment assembly comprising:
an external housing having a front end, a back end, a vertical first side panel, a vertical second side panel opposite said first side panel, a bottom end section, a top end section, a least one output port formed in said top end section, and two inlet ports formed in said bottom section and located on opposite sides of said bottom section;
a fan holding device within said top end section;
two or more fans mounted on said fan holding device;
an interior vertical wall mounted in said external housing so as to extend substantially perpendicular to said first and second side panels, said vertical wall being positioned between and spaced from said front and said back of the housing and having an upper edge spaced below said fan holding device, and dividing said housing into front and back cavity regions;
a first set of electronic apparatuses mounted in said front cavity region and forming vertically extending first air flow passages between adjacent pairs of said electronic apparatuses;
a second set of different electronic apparatuses mounted in said second cavity region and forming second, vertically extending air flow passages; and
a plenum region formed in said housing between said front and back cavity regions and said fan holding device, said plenum region extending horizontally across an upper edge of the interior vertical wall,
wherein, during use of said assembly, said two or more fans operate to create a pressure differential in said plenum region that produces upwards air flow through both said first and second air flow passages and into said plenum region.

17. A telecommunications equipment assembly according to claim 16 further comprising another fan holding device within said top end section, said fan holding devices extending from said first side panel to said second side panel.

18. A telecommunications equipment assembly according to claim 16 wherein said interior vertical wall is a midplane provided with electronic circuitry and said midplane extends between and is connected to the first and second side panels.

19. A telecommunications equipment assembly according to claim 16 wherein there are two of said at least one output port formed in said top end section and said two output ports are formed in opposite vertical sides of said top end section.

20. A telecommunications equipment assembly according to claim 16 wherein said top end section of said external housing is a fan cage having a plurality of grill areas for the passage of air through said top end section, said grill areas being formed in a horizontal top and at least one side wall of the fan cage.
